(19) United States
(12) Patent Application Publication
(10) Pub. No.: US 2025/0189180 A1
(43) Pub. Date: Jun. 12, 2025

(54) APPARATUS FOR AMPLIFYING COOLING VIA INTERACTION WITH ELECTROMAGNETIC RADIATION AND ANTI-STOKES FLUORESCENCE

(71) Applicant: SolCold Ltd., NES ZIYYONA (IL)

(72) Inventors: Yaron SHENHAV, Herzliya (IL); Maayan FOX, Petah Tikva (IL); Tzvi TEMPLEMAN, Rehovot (IL)

(21) Appl. No.: 18/715,131

(22) PCT Filed: Dec. 1, 2022
(86) PCT No.: PCT/IL2022/051285

§ 371 Date: May 31, 2024

(30) Foreign Application Priority Data
Dec. 2, 2021 (IL) 288642

(51) Int. Cl. F25B 23/00; F28F 13/18; H10F 77/30

(52) U.S. Cl. CPC F25B 23/003; F28F 13/18; H10F 77/334; F28F 2245/06

(57) ABSTRACT

The invention is an apparatus for amplifying cooling through interaction with electromagnetic radiation for optical of objects and/or object surfaces with essentially three layers, which are a bottom layer that is comprised of a single or multi layered material configured to emit IR radiation; a middle layer that is comprised of a single or multi layered material configured to respond in anti-Stokes fluorescence upon absorption of electromagnetic radiation; and a top layer that is comprised of a single or multi layered material configured to reflect selected spectral band(s) and/or amplify selected spectral band(s) of the electromagnetic radiation transmittable to the middle layer.

### FIELD OF THE INVENTION

The present invention relates to cooling surfaces of objects and objects. More specifically, the present invention pertains to cooling surfaces of objects and objects via anti-stokes fluorescence.

### BACKGROUND

Fluorescent materials are known for absorbing radiation in short wavelengths and emitting radiation in long wavelength with a certain emittance shape described as Stokes shift. The emission of such fluorescent materials may occur via Stokes/anti-Stokes shift. Such well known phenomenon of fluorescent materials is being used in various applications where bright color is needed including in biology and physics as a nondestructive method for analysis and cellular imaging.

Fluorescent materials are used in various other applications including employment of Forster resonance energy transfer (FRET), fluorescence recovery after photobleaching (FRAP), chemical sensors, optoelectronic devices, displays and labeling agents for detection.

Fluorescent substances are characterized based on their quantum yield and fluorescence lifetime. Quantum yield can be described as the number of emitted photons relative to the number of absorbed photons. The possible value of quantum yield ranges from 0 to 1. Lifetime is defined by the average time that the molecule stays in its exited state prior to return to the ground state.

Blackbody radiation of a substance is a phenomenon whereby the substance loses some of its thermal energy through vibration-induced photon emission from its surface. With a temperature around 300K, blackbody radiation is emitted and absorbed by a substance at wavelengths largely between 5-50 μm, referred to as long wave-far infra-red (LW-FIR) light.

A substance exposed to the clear sky will experience cooling due to the net loss of LW-FIR photons. This cooling effect is due to two separate phenomena: (a) the first being the existence of an atmospheric transparency band spanning 8-14 μm (“atmospheric window”) through which terrestrial photons can be emitted directly to space; as the temperature of space is around 4K, the returning blackbody radiation is negligible, and (b) the second is the dropping temperature of the atmosphere with height; the temperature of the atmosphere can be significantly lower than that of the surface of the earth, such that terrestrial blackbody photons are absorbed by the atmosphere from 14 μm and on, yet less photons are reemitted towards the surface due to the lower temperature of the atmosphere.

The total blackbody cooling of a substance at 300K can achieve flux values on the order of 150 W/m², which when combined with high (>90%) solar reflectivity can yield surfaces which cool to below ambient temperatures even during the day. Obstruction of the clear sky due to clouds, humidity, greenhouse gasses or other radiative bodies lowers the net radiative cooling flux.

Taking the conservative estimate of 20 W/K*m² for the surface-air convection coefficient in a light breeze, it is possible to achieve one degree of sub-ambient cooling for every 20 W/m² of net radiation emitted from the surface; this requires both rejecting nearly all solar radiation (˜1 kW/m²), and powerfully emitting blackbody radiation—primarily to space through the atmospheric window, and additionally across the remaining spectrum to the cooler atmosphere.

Laser cooling of solids is a phenomenon in which interaction with radiation is causing effective cooling in solid materials. The idea was proposed as early as 1929 by Pringsheim. However, it wasn't until 1995 that laser cooling of solids was achieved by Epstein et al., who managed to cool a solid by 0.3K (Epstein 1995), also called optical refrigeration of solids.

Laser cooling is a fast-growing field, with the state of the art being the cooling of solids to cryogenic temperature as low as 100K (Melgaard 2016). In the solid phase of matter a large amount of the thermal energy of the matter is contained in the vibrational modes of the lattice. Thus, a decrease in the vibrational motion of the particles results in cooling of the material. In analogy to quanta of light, the quanta of vibrational motion are usually referred to as phonons.

The two main interactions that are important for laser cooling are: (a) Stokes fluorescence/scattering, which is a process in which light interacts with matter whereby a photon is absorbed and remitted with lower energy, the process is sometimes also luminescence down conversion. The lost energy is converted into thermal energy within the solid. These results in heating of the interacting material, and (b) Anti-Stokes fluorescence/scattering (also termed luminescence up conversion). In this process, light interacts with matter so that each photon is scattered with more energy than the energy it started with. The energy is provided by the phonons in the material, leading to cooling of the material after equilibration.

The physical principles of laser cooling in solids aims at achieving maximum anti-Stokes scattering and minimum Stokes scattering. Since the type of scattering is highly dependent on the wavelength of the light, lasers, that emit light with a narrow range of wavelengths, have been traditionally used for such studies.

Laser cooling using anti-Stokes fluorescence has been investigated and established for some time. Such cooling is achieved due to emission of electromagnetic radiation (photons) with mean energy that is higher than the mean energy of the absorbed radiation. Effectively, heat is converted into light that is emitted from the material. Radiative emission with higher energy than the absorbed radiation can be modeled with semiconductors having energy band gap between ground and excited levels and a splitting of energy level between two excited levels, where the band gap is an order of magnitude greater than the energy gap between the excited levels. Thermal equilibrium between the two excited level results in population of the higher excited level. Assuming no non-radiative decay of the excited electrons in the higher excited level, then photon emission takes place with frequency higher (shorter wavelength) than the frequency of the photons absorbed, resulting in net cooling.

Laser cooling of solids at the present time can be largely divided into two areas: laser cooling with ion doped glasses or crystals, and laser cooling in semiconductors (bulk or confined, like quantum-well structures), an example of a usage is in radiation-balanced lasers, where the pump wavelength is adjusted so that the anti-Stokes fluorescence cooling compensates for the laser heating.

Anti-Stokes solid state coolers, also termed optical coolers, based on the first two options above are effective in reaching temperatures as low as 80K for rare earth (RE) doped glass and 55 K for direct band gap semiconductors.

The main advantage of RE-ions is the optically active 4f electrons shielded by the filled 5s and 5p outer shells, which limit interaction with the lattice surrounding the RE-ion and suppress non-radiative decay. Hosts with low phonon energy, for example, fluoride glasses and crystals, can diminish non-radiative decay and increase quantum efficiency.

Laser-induced cooling has been observed in a wide variety of glasses and crystals doped with ytterbium (Yb³⁺) such as ZBLANP, ZBLAN, CNBZn and BIG, YAG and Y₂SiO₅, BaY₂F₈, KPb₂Cl₅, KGd₂ and KY₂, YLF. Laser-induced cooling has been also observed in thulium (Tm³⁺) doped ZBLANP and BaY₂F₈, and in erbium (Er³) doped CNBZn and KPb₂Cl₅.

### Temperature Measurement—IR Camera

All objects emit radiation whose spectrum is dependent on the object's temperature. This radiation is termed black body radiation because in the theory black bodies absorb all the radiation that falls on them and therefore are “black”. For temperatures around room temperature the emitted radiation is concentrated mostly at the mid and far-IR part of the spectrum, with wavelengths of around 10 micrometers. IR cameras contain detectors that measure the intensity of photons with these wavelengths. These cameras allow to measure the temperature of a body from a distance, assuming the media through which the photons propagate is transparent to these photons. By measuring the intensity of the IR light, the temperature is easily calculated. In particular, even without calibration, temperature differences and evolution trends can be easily identified.

### Temperature Measurements Methods—Diode

This method directly measures the temperature of a small diode, which is thermally coupled to the sample one wishes to measure. The voltage drop across the diode increases as its temperature rises by a known amount.

Temperature Measurements methods—fluids regimes—This method is looking at the regimes inside fluids during light absorption to determine the minor temperature changes using the direction in which the fluid moves in different areas inside the vile.

### Newton Cooling Model:

Newton cooling is a theory that describes the heat exchange of a body with the environment. The theory assumes that the rate of cooling depends on the temperature difference, giving an exponential solution. Using this solution with adding a constant heat/cooling source gives the equation:

$$\frac{d ( Δ T )}{dt} = - {P}_{cooling} * \frac{1}{C} + b * ( Δ T ) \\ C = \frac{1}{b} * L * k = [ \frac{W * s}{K} ] \\ \frac{Volume}{Area} = L = effective length \\ k = constant of the material = \frac{1 W}{K * m} for glass \\ Δ T = {T}_{0} - \frac{{P}_{cooling}}{L * k} + \frac{{P}_{cooling}}{L * k} * {e}^{- bt}$$

### Sunlight Simulators

Sunlight simulators are devices that emit light with a spectrum closely matching the solar spectrum impinging on the Earth (after accounting for atmospheric effects). The following graph shown in FIG. 1 (PRIOR ART), produced by the ASTM (American Society for Testing and Materials), shows the intensity of light that reaches the earth as a function of wavelength, with and without atmospheric absorption of light, also referred to as the sun's light spectrum. In addition, it shows the theoretical spectrum as expected by a black body with a temperature of 5778K shown in the solid line) with and without the atmospheric absorption, like the temperature of the sun's surface.

The following details some basic models for anti-Stokes cooling in RE-doped glass (the 4-level model) and semiconductors.

### The 4-Level Model for Optical Refrigeration

Consider basic concepts of laser cooling of solids using Yb³⁺:ZBLANP sample as an example. Energy levels in cm-1 and major transitions of Yb³⁺ in ZBLANP are illustrated in FIG. 2A (PRIOR ART). The systems of levels illustrated in FIG. 2A can be approximated by the 4-level system illustrated in FIG. 2B (PRIOR ART).

In this 4-level system the ground state manifold (2F7/2) is presented by two energy levels with an energy separation δEg=E1−E0, corresponding to the bottom (E0) and to the top (E1) of this manifold. The excited manifold (2F5/2) is presented by two energy levels with an energy separation SEex=E3−E2, corresponding to the bottom (E2). FIG. 2A illustrates the energy levels and major transitions of Yb³⁺ in ZBLAN.

FIG. 2B illustrates the 4-level energy model for optical refrigeration consisting of two pairs of levels in the ground (0 and 1) and excited (2 and 3) manifolds.

### Optical Cooling in Semiconductors

The recent advances in the development and fabrication of semiconductors have stimulated an interest in semiconductors as candidates for optical cooling. The essential difference between semiconductors and rare-earth doped materials is in their cooling cycles. In the case of RE-doped glasses, the cooling transition occurs in localized donor ions within the host. In the case of semiconductors, the cooling cycle involves transition between extended valence and conduction bands of a direct band gap semiconductor. Laser photons with energy hvp create a cold distribution of electron-hole carriers. The carriers then heat by absorbing phonons followed by an up-converted luminescence at hvf.

FIG. 3 (PRIOR ART) schematically illustrates the cooling cycle in a semiconductor with hvp absorbed energy followed by emission of an up-converted luminescence photon at hvf.

Indistinguishable charge carries in Fermi-Dirac distributions allow semiconductors to be cooled to lower temperatures than RE-doped materials. Indeed, the highest energy levels of the ground state manifold in the RE-doped systems become less populated as soon as the temperature is lowered, due to the Boltzmann distribution. The cooling cycle in RE-doped hosts ceases when the Boltzmann constant times the lattice temperature becomes comparable to the width of the ground state. No such limitation exists in un-doped semiconductors. Following theoretical estimations, temperatures as low as 10 K may be achieved in laser cooled semiconductors. It has been shown that the lattice and the carriers can have different temperatures varying in space and time.

Although semiconductors are very promising materials for laser cooling of solids and their external quantum efficiency increases with decreasing temperature, since the loss terms A and C decrease and the radiative rate (B coefficient) increases inversely with the temperature there are some problems which must be overcome in order to achieve net cooling of semiconductors experimentally, where the loss terms A, B and C mentioned above, define the nonradiative, radiative and Auger rates of electron-hole recombination.
(1) The surface recombination rate has to be reduced. Well developed epitaxial growth technique such as metal organic chemical vapor deposition (MOCVD), which can provide very low surface recombination rate (A<104 sec-1) can be considered as a promising solution of the problem. In this case, an active layer of GaAs is sandwiched between two thin layers of AlGaAs or InGaP. These lattice-matched cladding layers provide surface passivation and carrier confinement at the same time and
(2) the parasitic background absorption has to be reduced. The background absorption can be reduced during material preparation with well-developed epitaxial methods. The extraction efficiency can be enhanced if total internal reflection, which causes trapping and re-absorption of spontaneous emission, can be prevented. At the present time the purity of the samples is the main obstacle on the path to achieving net laser cooling in semiconductors.

Candidate materials which have an energy-level diagram similar to the one drawn in FIGS. 2A, 2B and 3 include semiconductors (excited across their band gaps), rare-earth or transition-metal doped crystals and glasses, and polyatomic molecules in any phase (excited between vibration levels).

FIG. 2A (PRIOR ART) shows the 4-level model for optical refrigeration for RE-doped glass, for example Yb³:ZBLANP. Although the diagram initially relates to laser cooling, it is equally relevant to wide band radiation.

FIG. 2B illustrates a particular calculation for the 4-level model (units in cm-1).

FIG. 3 is a schematic illustration of optical cooling in semiconductors. The up-conversion of the excited photons resulting from thermal equilibrium between neighbor excited energy levels leads to photon emission with energy higher than that of the photon absorbed. Thus the optical cooling effect in semiconductor materials is achieved by phonons absorption and conversion of thermal energy to electromagnetic energy.

FIG. 4 (PRIOR ART) is an example plot of measured maximum ΔT (squares) and theoretically calculated temperature change curve (solid line) normalized to the pump power in K/mW for different pump wavelengths at 290K. The solid region corresponds to the cooling zone for Cadmium Sulfide engineered material. A drop of temperature resulting from absorption of photons with wavelengths between 505 nm and 560 nm can clearly be seen. Applying to wide band radiation as in the present invention, using a ˜505 nm-˜560 nm spectral band extracted from the solar radiation on Cadmium Sulfide would generate anti-Stokes fluorescence resulting in effective cooling.

Various anti-Stokes based cooling technologies based on the requirement for excitation by laser and tuning to very specific radiation wavelength are available nowadays. Such technologies are efficient for particular applications where very low temperature is required and monochromatic radiation is used.

An anti-Stokes based cooling method appliable at conditions of temperature and non-monochromatic radiation has been introduced for the first time by SolCold, the Applicant of the present application on 2018 (WO201820503).

In WO201820503, the applicant replaces the energy source, namely the laser pump, with a more naturally available wider spectrum source of radiation, e.g. taken from the solar spectrum and tailors the spectral band to match the material exhibiting anti-Stokes florescence. More specifically, WO201820503 relates to a double or multi-layer apparatus or device for optical anti-Stokes cooling of object surfaces. The apparatus comprises at least one bottom layer, which is configured to respond in anti-Stokes fluorescence upon absorption of electromagnetic radiation and at least one top layer, which is overlaid on the bottom layer and configured to filter the electromagnetic radiation and transmit selected spectral band of the electromagnetic radiation to the bottom layer. The active cooling does not depend on the coherent nature of the radiation, which enables the usage of incoherent solar radiation as the active cooling input power source.

It is now an object of the present invention to improve the technology for cooling larger scale objects and surfaces using anti-Stokes effect.

More specifically, it is an aim of the present invention to provide an improved apparatus for anti-Stokes based cooling of objects and surfaces by using the solar radiation, e.g., an improved apparatus amplifying the cooling mechanism based on absorption of electromagnetic/solar radiation and anti-Stokes fluorescence.

### SUMMARY OF THE INVENTION

The present invention pertains to amplify a cooling mechanism based on absorption of incoherent non-monochromatic electromagnetic/solar radiation and anti-Stokes fluorescence. The present invention relates to fabrication and experimental measurements of solid composite materials of highly fluorescent molecules and nano-materials. These materials have been specifically investigated and found to be rather optional good candidates to be utilized as active anti-Stokes cooling layers in various embodiments of this invention. Such layers can be induced to operate by either lasers or solar radiation at certain wavelength ranges.

In accordance with some embodiments of the present invention, there is thus provided an apparatus for amplifying a cooling mechanism based on absorption of incoherent non-monochromatic electromagnetic/solar radiation and anti-Stokes fluorescence, said apparatus comprising:
at least one bottom layer, said at least one bottom layer is comprised of a single or multi layered material configured to reflect said electromagnetic radiation and/or to emit IR radiation;
at least one middle layer, said at least one middle layer is comprised of a single or multi layered material configured to respond in anti-Stokes fluorescence upon absorption of electromagnetic radiation; and
at least one top layer, said at least one top layer is comprised of a single or multi layered material configured to filter said electromagnetic radiation and transmit selected spectral band of said electromagnetic radiation transmittable to said said middle layer and bottom layer, wherein said middle layer is configured to respond to one of said selected spectral band(s), wherein said bottom layer is configured to respond to a second of said selected spectral band(s), wherein said one and second spectral bands are the same as or different from each other.

In accordance with some embodiments of the present invention, there is thus provided, an apparatus for amplifying electromagnetic radiation for optical cooling of objects and/or object surfaces, said apparatus comprising:
at least one bottom layer, said at least one bottom layer is comprised of a single or multi layered material configured to respond in anti-Stokes fluorescence upon absorption of electromagnetic radiation; and
at least one top layer, said at least one top layer is comprised of a single or multi layered material configured to amplify selected spectral band(s) of said electromagnetic radiation transmittable to said bottom layer.

Furthermore, in accordance with some embodiments of the present invention, there is provided an apparatus for amplifying electromagnetic radiation for optical cooling of objects and/or object surfaces, said apparatus comprising:
at least one bottom layer, said at least one bottom layer is comprised of a single or multi layered material configured to reflect said electromagnetic radiation and/or to emit IR radiation;
at least one middle layer, said at least one middle layer is comprised of a single or multi layered material configured to respond in anti-Stokes fluorescence upon absorption of electromagnetic radiation; and
at least one top layer, said at least one top layer is comprised of a single or multi layered material configured to amplify selected spectral band(s) of said electromagnetic radiation transmittable to said middle layer.

Furthermore, in accordance with some embodiments of the present invention, the at least one top layer is configured to filter said electromagnetic radiation and to transmit selected spectral band(s) of said electromagnetic radiation to said middle layer.

Furthermore, in accordance with some embodiments of the present invention, the apparatus further comprising a filtering layer either on top or below the at least one top layer.

Furthermore, in accordance with some embodiments of the present invention, the bottom layer is configured to reflect at least 50% of the electromagnetic radiation.

Furthermore, in accordance with some embodiments of the present invention, the apparatus further comprising at least one layer configured to emit IR radiation.

Furthermore, in accordance with some embodiments of the present invention, the apparatus further comprising at least one insulation layer. In some embodiments, the insulation layer is transparent to electromagnetic radiation. In still other embodiments, the insulation layer is a microporous film with pores with diameter smaller than 5 μm. In still other embodiments, the materials that make the insulation film are very low IR absorption polymers and materials selected from HDPE, Nylon 6, and Nylon 6,6, and iodide and bromide salts. In still other embodiments, the Nylon 6 or Nylon 6,6 is a woven fabric. In still another embodiment, the insulation layer is air. In some embodiments of the present invention, the insulation film is made of materials that are ITVOF (Infrared Transparent Visible Opaque). In still other embodiments, the thickness of the insulation layer ranges between millimeters and centimeters, e.g., 1 millimeter-10 centimeters, where its transparency to electromagnetic radiation, particularly IR radiation, reduces proportionally to its thickness. In some embodiments, the insulation layer is made of a material that is selectively transparent to electromagnetic radiation. In still other embodiments, the electromagnetic radiation selectively transparent material is selected from porous PTFE, PMMA (Polymethylmethacrylate), PS (Polystyrene) and Germanium films. Preferably, the thickness of the porous PTFE film is in the range of 0.3-2 μm. In still another embodiment, the Germanium film is transparent between 8-13 μm.

Furthermore, in accordance with some embodiments of the present invention, the apparatus further comprising at least one adhesive layer underneath the bottom layer for attaching said apparatus to an object to be cooled.

Furthermore, in accordance with some embodiments of the present invention, the apparatus further comprising at least one upper mechanical layer to secure said apparatus against mechanical deterioration.

Furthermore, in accordance with some embodiments of the present invention, the multiple layers are linked to each other through an adhesion matrix domain.

Furthermore, in accordance with some embodiments of the present invention, the at least one bottom layer and/or said at least one top layer and/or said at least one middle layer are provided in film(s).

Furthermore, in accordance with some embodiments of the present invention, the at least one layer is either continuous or non-continuous to allow communication frequencies to pass therethrough.

Furthermore, in accordance with some embodiments of the present invention, the electromagnetic radiation is incoherent non-monochromatic radiation with wide spectral band, wherein said selected spectral band is sufficient for excitation of electrons from ground energy state to excited energy state in active component in said bottom layer.

Furthermore, in accordance with some embodiments of the present invention, the electromagnetic radiation is incoherent non-monochromatic radiation with wide spectral band, wherein said selected spectral band is sufficient for excitation of electrons from ground energy state to excited energy state in active component in said middle layer.

Furthermore, in accordance with some embodiments of the present invention, the at least one top layer is comprised of a fluorescent material with QY of at least 80%.

Furthermore, in accordance with some embodiments of the present invention, the at least one top layer is comprised of at least one material selected from Pyranine, Perovskites, 1 1,3-Bis[4-(dimethylamino)phenyl]-2,4-dihydroxycyclobutenediylium dihydroxide, bis(inner salt) [Squarylium dye III], Cyanine-3b (Cyanine family), Pyrromethene 567 (Bodipy Family), Perylene, Coumarin 6 (Coumarin Family), 9,10-Bis(phenylethynyl)anthracene, 1,4-bis(5-phenyloxazol-2-yl) benzene (POPOP), Perylene, PMI, Perylene, PMI(OR), Perylene, PMI(OR)3, Perylene, PDI, Fluorescein, Rhodamine 123, Rhodamine 6G, Rhodamine 101 inner salt, Sulforhodamine 101, and Rhodamine family and derivatives.

Furthermore, in accordance with some embodiments of the present invention, for reflecting selected wavelength band of solar radiation the at least one bottom layer comprises continuous or porous PTFE (Polytetrafluoroethylene), PDMS (Polydimethylsiloxane), HDPE (High Density Polyethylene), PS (Polystyrene), Silica, Germania, Alumina, Titania, Barium Sulfate or nano or microparticles of the same, where the nano or microparticles are free-standing or embedded in a film, matrix or membrane.

In still some other embodiments of the present invention, the pore diameter of the bottom solar reflection layer is in the range from 0.2 to 2 microns. In still other embodiments of the present invention, the solar radiation reflection bottom layer comprises micro-particles of the same diameter of such pores, namely 0.2-2 microns, where these micro-particles are uniformly dispersed in the volume of the layer.

For particles in the solar radiation reflection layer, radiation scattering is made at the particles boundaries, namely scattering events. Therefore, there is a tradeoff between particle size in a film of the solar reflection layer and number of scattering events, which are determined according to the number of particles. Optimizing reflection would therefore need to balance between ideal particle size as an individual scatterer and number and distribution of particles in the film.

Furthermore, in accordance with some embodiments of the present invention, the solar radiation reflection layer is a film with a thickness in the range of 1-1000 microns.

Furthermore, in accordance with some embodiments of the present invention, the at least one bottom layer is comprised of a fluorescent material with QY of at least 90%.

Furthermore, in accordance with some embodiments of the present invention, the at least one bottom layer is comprised of at least one material selected from Cadmium Sulfide, Gallium Arsenide (GaAs) quantum wells, Ytterbium-doped yttrium lithium fluoride (Yb:YLF) crystal, Ytterbium-doped tungstate crystal (Yb:KGW), Fluorozirconate glass (ZBLANP) doped with 1 wt % Yb3+, 9Be+, Cesium, CdS/ZnS, Perovskites, Pyranine, 20 BPEA, Rhodamine 101 (Xanathine family), and Pyrromethene 567 (Bodipy family). Furthermore, in accordance with some embodiments of the present invention, the at least one middle layer is comprised of a fluorescent material with QY of at least 90%. Furthermore, in accordance with some embodiments of the present invention, the at least one middle layer is comprised of at least one material selected from Cadmium Sulfide, Gallium Arsenide (GaAs) quantum wells, Ytterbium-doped yttrium lithium fluoride (Yb:YLF) crystal, Ytterbium-doped tungstate crystal (Yb:KGW), Fluorozirconate glass (ZBLANP) doped with 1 wt % Yb3+, 9Be+, Cesium, CdS/ZnS, Perovskites, Pyranine, BPEA, Rhodamine 101 (Xanathine family), and Pyrromethene 567 (Bodipy family). Furthermore, in accordance with some embodiments of the present invention, the at least one bottom layer is comprised of at least one material selected from Continuous or Porous PTFE or PTFE nano or micro particles, Continuous or Porous PDMS or PDMS nano or micro particles, Continuous or Porous SiO₂ or SiO₂ nano or micro particles, Continuous or Porous etched ceramics such as Alumina, TiO₂, BaSO₄, Metal, SiO₂, Si-Polymers. Furthermore, in accordance with some embodiments of the present invention, the at least one bottom layer is made of porous substance with strong optical activity in a LW-FIR region.

Furthermore, in accordance with some embodiments of the present invention the bottom layer comprises a continuous PDMS film for emission of black body radiation within the atmospheric window of 8-14 μm. In one particular embodiment, the thickness of the continuous PDMS film in the bottom layer ranges between 3.5 μm and 5 μm. In still another particular embodiment, the thickness of the continuous PDMS film in the bottom layer is 4 μm.

In other embodiments of the present invention, the PDMS film in the bottom layer is porous with a total mass that is approximately equal to the mass of a continuous PDMS film with a thickness in the range of 3.5 to 5 μm, preferably with a thickness of 4 μm. In still other embodiments of the present invention, the diameter of the pores in the porous PDMS film is in the range of 8-14 μm, where these pores are uniformly dispersed in the volume of the film.

In still other embodiments of the present invention, the PDMS film in the bottom layer further comprises electromagnetic radiation emitters at a wavelength of 11 μm, due to the relatively low emission of PDMS at this wavelength. In some embodiments, these emitters are selected from SiC, BaSO₄ and ZnO. In still other embodiments, the emitters are provided as particles with a relatively low diameter of about 0.3 μm. In still other embodiments, the emitters are provided as particles with a relatively higher diameter in the range of 8-13 μm.

Furthermore, in accordance with some embodiments of the present invention, the apparatus is exposed to the sun and/or positioned under a transparent object and/or positioned underneath a perforated object.

Furthermore, in accordance with some embodiments of the present invention, the apparatus cools solids, liquids and vapors.

Furthermore, in accordance with some embodiments of the present invention, the apparatus is provided in paint.

Furthermore, in accordance with some embodiments of the present invention, the apparatus is incorporated in a textile.

Furthermore, in accordance with some embodiments of the present invention, the at least one top layer is incorporated into outer surface of fibers of said textile, the at least one bottom layer is incorporated into a core of said fibers, and the at least one middle layer is incorporated in between the outer surface of the fibers and the core of the fibers.

Furthermore, in accordance with some embodiments of the present invention, the apparatus having physical and chemical compatibilities with surfaces of different materials.

### BRIEF DESCRIPTION OF THE DRAWINGS

FIG. 1 (PRIOR ART) shows the spectrum of the sun, which is modeled as a black body with a temperature of 5778K (shown in the solid line) with and without the atmospheric absorption.

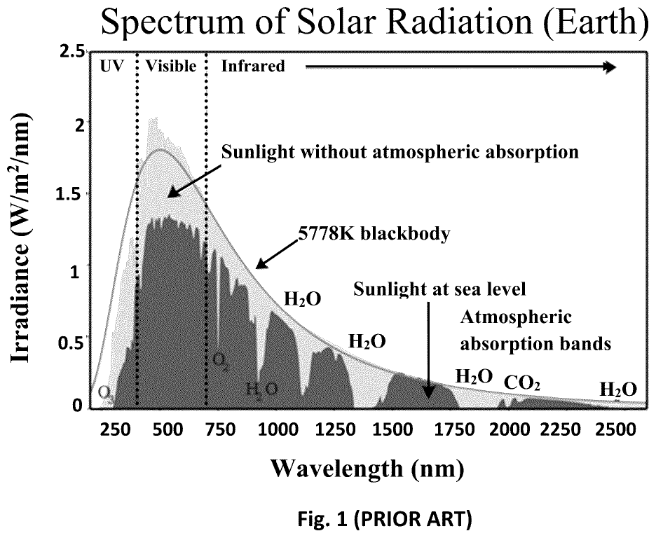

FIG. 2A (PRIOR ART) shows the 4-level model for optical refrigeration.

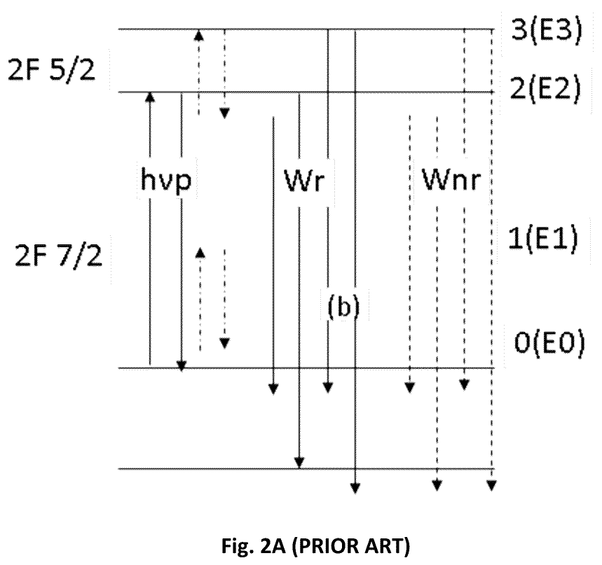

FIG. 2B (PRIOR ART) shows an example of the 4-level model for optical refrigeration.

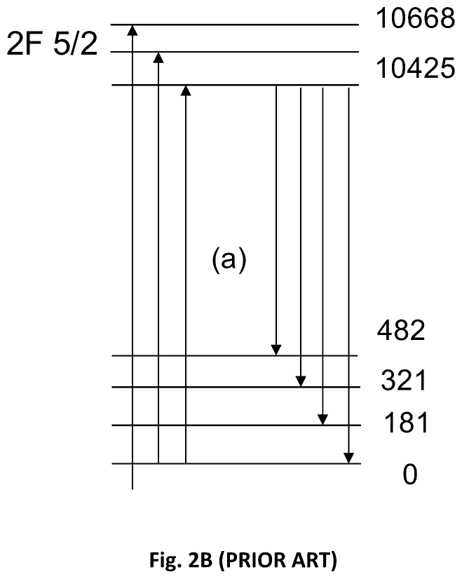

FIG. 3 (PRIOR ART) shows the semiconductor model for optical refrigeration.

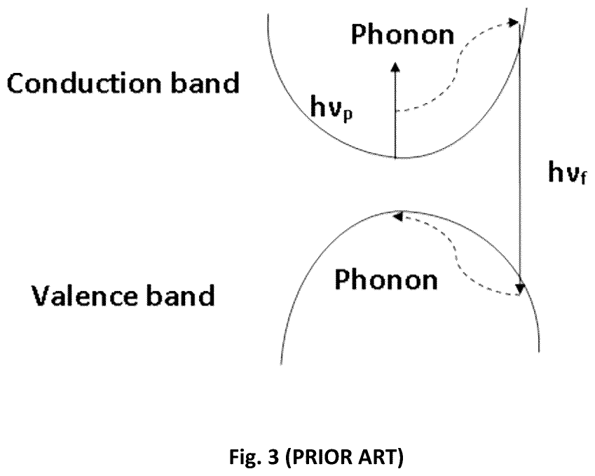

FIG. 4 (PRIOR ART) shows a plot of calculated temperature change with optical cooling.

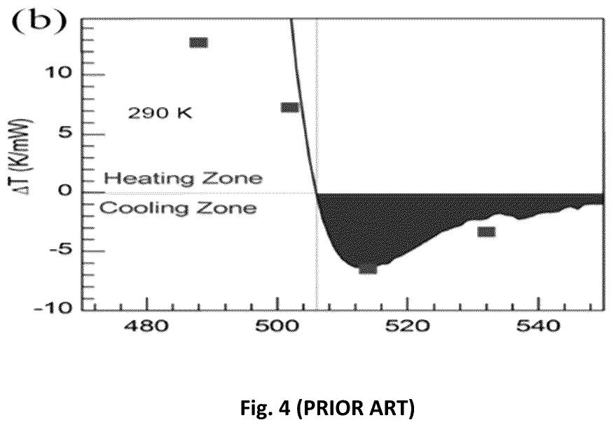

FIG. 5A illustrates a first apparatus for amplifying electromagnetic radiation and cooling of objects and/or object surfaces via anti-Stokes fluorescence in accordance with some embodiments of the present invention.

FIG. 5B illustrates a second apparatus for amplifying electromagnetic radiation and cooling of objects and/or object surfaces via anti-Stokes fluorescence in accordance with some embodiments of the present invention.

FIG. 5C illustrates a third apparatus for amplifying electromagnetic radiation and cooling of objects and/or object surfaces via anti-Stokes fluorescence in accordance with some embodiments of the present invention.

FIG. 5D is a schematic illustrating the various layers and possible locations of each layer in an apparatus for amplifying electromagnetic radiation and cooling of objects and/or object surfaces via anti-Stokes fluorescence in accordance with some embodiments of the present invention.

FIG. 5E is a schematic illustrating an apparatus for amplifying electromagnetic radiation and cooling of objects and/or object surfaces via anti-Stokes fluorescence comprised of multiple layers in accordance with some embodiments of the present invention.

FIG. 6 is intensity as a function of time plot showing a Stokes shift of Pyranine dye amplifying the solar spectrum.

FIG. 7 schematically illustrates one particular implementation of the apparatus for optical cooling of objects and/or object surfaces of the present invention.

FIG. 8 shows the results of a cooling experiment carried out outdoors with the apparatus for optical cooling of objects and/or object surfaces.

FIG. 9 shows the results of a cooling experiment carried out indoors with the apparatus for optical cooling of objects and/or object surfaces.

FIG. 10 models cooling with anti-Stokes fluorescence in a multi-layer apparatus that comprises insulation for amplifying electromagnetic radiation of the present invention.

### DETAILED DESCRIPTION OF THE FIGURES

The present invention is of an apparatus for amplifying electromagnetic radiation and cooling of objects and/or object surfaces via anti-Stokes fluorescence. More specifically, the present invention is of a multi-layer apparatus for amplifying electromagnetic radiation and optical anti-Stokes and radiative cooling of object surfaces via materials that respond to wide band solar radiation.

In accordance with some embodiments of the present invention, the apparatus for amplifying electromagnetic radiation and cooling of objects and/or object surfaces via anti-Stokes fluorescence 100 extracts and amplifies selected spectral bands from the solar radiation for anti-Stokes florescence cooling, thus, generates cooling effect in an object on which it is overlaid by emitting anti-Stokes fluorescence.

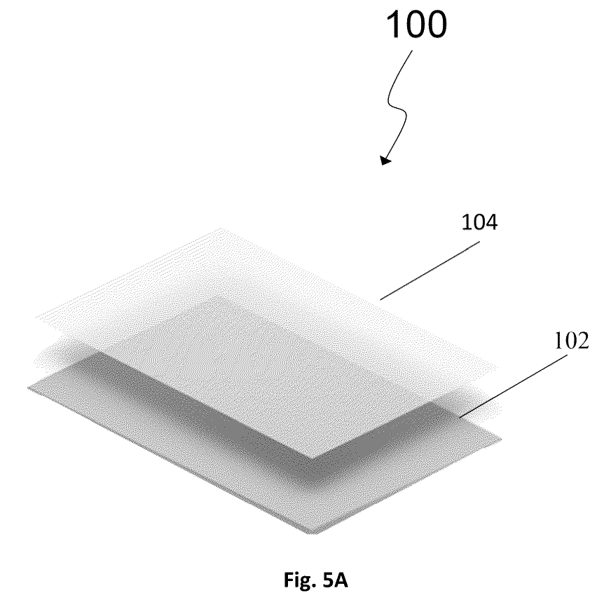

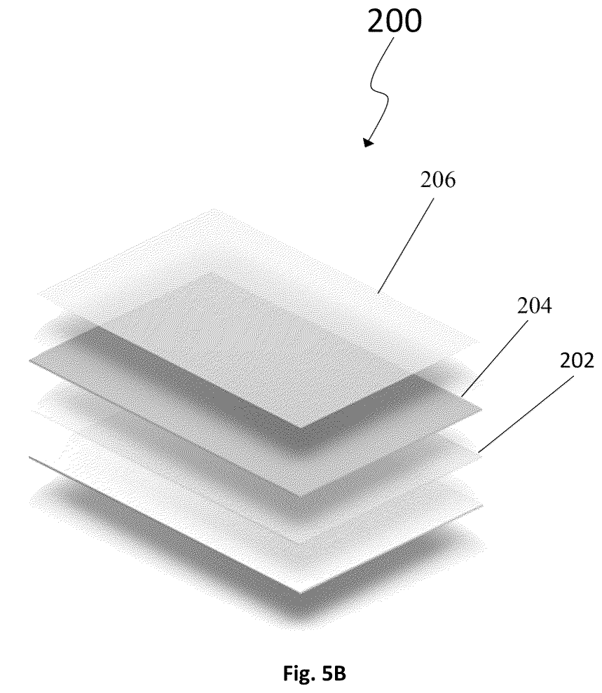

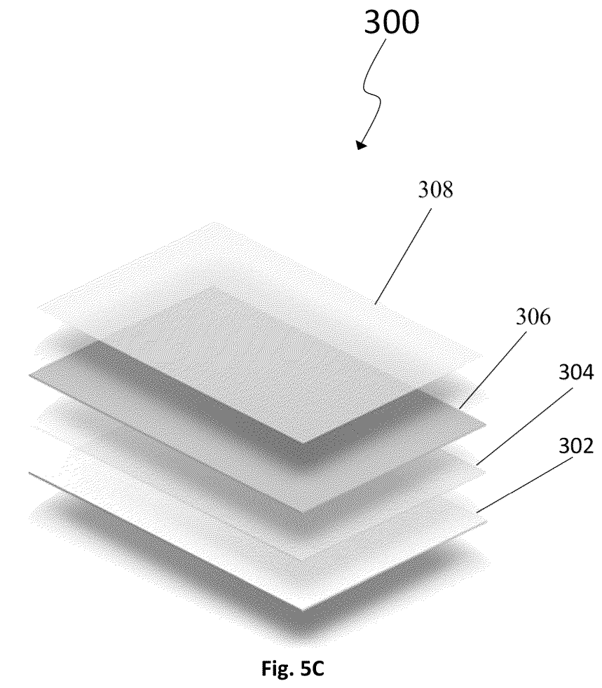

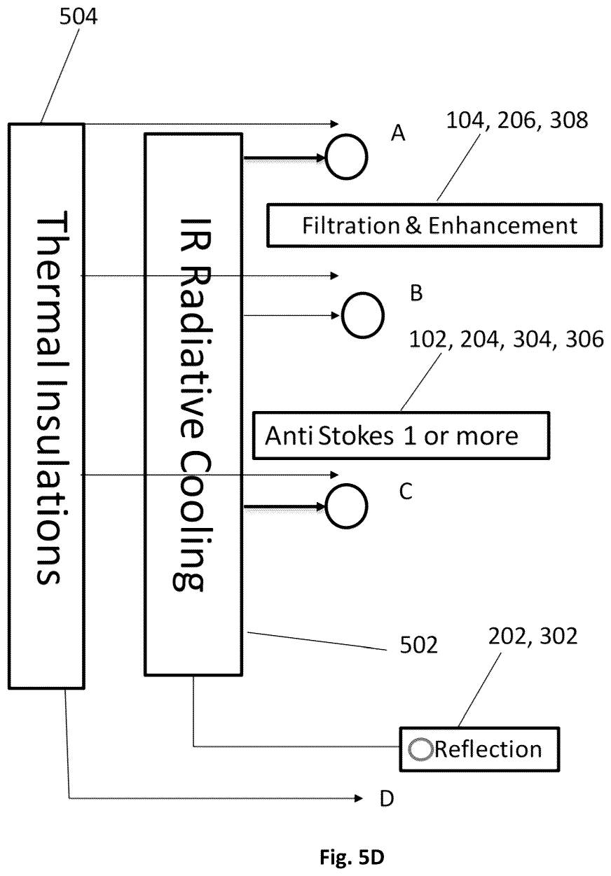

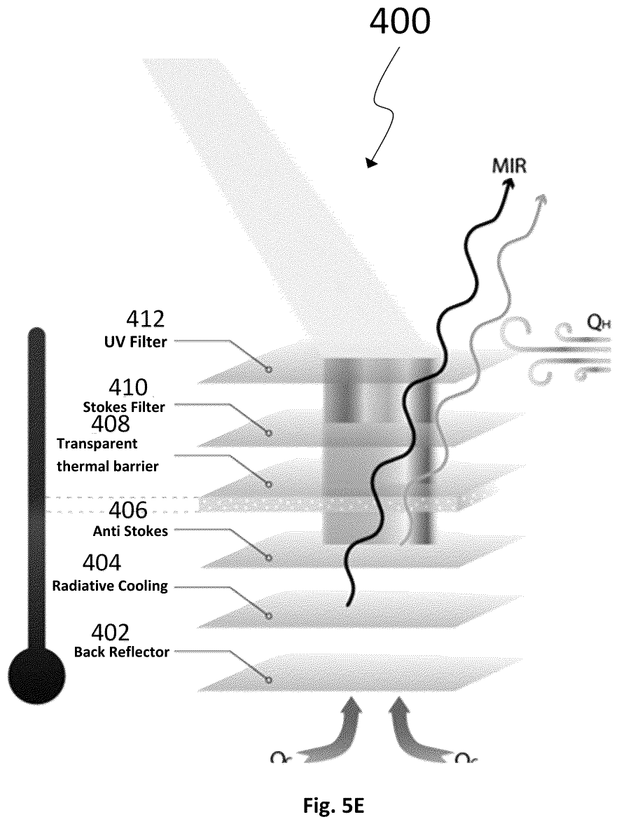

FIG. 5A illustrates a first apparatus for amplifying electromagnetic radiation and cooling of objects and/or object surfaces via anti-Stokes fluorescence 100 in accordance with some embodiments of the present invention.

In accordance with some embodiments of the present invention, the first apparatus for amplifying electromagnetic radiation and cooling of objects and/or object surfaces via anti-Stokes fluorescence 100 may comprise:
(a) at least one bottom layer 102 which is an active cooling layer comprised of a single or multi layered material configured to respond in anti-Stokes fluorescence upon absorption of electromagnetic radiation, and
(b) at least one top layer 104 which is an amplifying filter layer. The at least one top layer 104 is comprised of a single or multi layered material configured to amplify the electromagnetic radiation transmitted to bottom layer 102.

FIG. 5B illustrates a second apparatus for amplifying electromagnetic radiation and cooling of objects and/or object surfaces via anti-Stokes fluorescence 200 in accordance with some embodiments of the present invention.

In accordance with some embodiments of the present invention, the second apparatus for amplifying electromagnetic radiation and cooling of objects and/or object surfaces via anti-Stokes fluorescence 200 may comprise:
(a) at least one bottom layer 202 which is a reflective layer with/without IR emission. The at least one bottom layer 202 comprises a single or multi layered material configured to reflect at least 50% of the radiation and to emit IR radiation, e.g., the at least one bottom layer 202 may function as a reflector reflecting at least 50% of the radiation with the addition of IR emission,
(b) at least one middle layer 204 which is an active cooling layer comprised of a single or multi layered material configured to respond in anti-Stokes fluorescence upon absorption of electromagnetic radiation, and
(c) at least one top layer 206 which is an amplifying filter layer. The at least one top layer 206 is comprised of a single or multi layered material configured to amplify the electromagnetic radiation transmitted to the middle layer 204.

In accordance with some embodiments of the present invention, the apparatus for amplifying electromagnetic radiation and cooling of objects and/or object surfaces via anti-Stokes fluorescence 100, 200 may further include filtering capabilities, i.e., may provide a multi-layer structure that filters the radiation spectrum, amplifies a spectrum window using Stokes shift and transmits the selected band to the layer that displays anti-Stokes fluorescence.

In accordance with some embodiments of the present invention, the heat produced by Stokes shift in the at least one top layer 104, 206 may be less than the heat cooled by anti-Stokes fluorescence at the bottom layer 102/middle layer 204. That is, since the bottom layer 102/middle layer 204 may use not only the amplified electromagnetic radiation which is originally out of the spectrum window of anti-Stokes fluorescence but also the filtered electromagnetic radiation which is originally in the spectrum window, the cooling effect at the bottom layer 102/middle layer 204 may exceed the heating effect at the at least one top layer 104, 206. Moreover, in accordance with some embodiment of the present invention, all the heats produced by Stokes shift in the at least one top layer 104, 206 do not penetrate into the bottom layer 102/middle layer 204, since some of the heats dissipate to the surroundings.

In accordance with some embodiments of the present invention, the at least one top layer 104, 206 may filter the electromagnetic radiation to transmit selected spectral band of the electromagnetic radiation transmitted to the bottom layer 102/middle layer 204. The at least one top layer 104, 206, may include filtering means that selectively reflects light particle such as UV and some visible light, that are not useful for cooling. The filtration of light particles that are not useful for cooling prevents heating and degradation of the more sensitive layers underneath this layer. Therefore, the filtration layer is the outermost side exposed to the light source (sun).

In accordance with some embodiments of the present invention, the filtration and amplification capabilities of at least one layer may shield the objects and/or object surfaces from unnecessarily absorbed radiation and may actually render the cooling effect more efficient by increasing the ratio of radiation input-output via the amplification of the spectral bands transmitted to the bottom layer 102/middle layer 204.

The at least one filtering layer filters radiation by reflecting part of it back to the atmosphere, and the at least one amplification layer amplifies the spectral window entering by shifting some of the radiation to a certain band—the at least one amplification layer is embedded with Stokes shifters to shift photons from higher frequencies to lower frequencies to increase the photons flux in a desired band for anti-Stokes cooling, and transmitting a selected range of wavelengths, including the amplified bands to the active cooling layer, e.g., to the bottom layer 102/middle layer 204.

For instance, the at least one amplification layer may turn useless blue light into green light. Thus, the at least one amplification layer may amplify the natural green light with a blue light that has been turned to green.

Thus, in accordance with some embodiments of the present invention, at least one filtering layer may be situated either on top or below the at least one amplification layer. Alternatively, at least one layer, i.e., the at least one top layer, may have filtering and amplification capabilities.

As discussed above, the at least one top layer 104/206 may have filtering capabilities. Alternatively, additional layer(s) with filtering capabilities may be implemented on top/underneath the at least one top layer 104/206.

Thus, in accordance with some embodiments of the present invention, the role of the at least one top layer 104, 206 is three fold as it (a) may filter a radiation spectrum by reflecting part of it back to the atmosphere and/or by blocking it via absorption or by any other way, (b) may amplify the spectral window entering by shifting some of the radiation to a certain band (Stokes shift of shorter wavelengths), and (c) may transmit a selected range of wavelengths including the amplified bands to the active cooling layer, e.g., to the bottom layer 102/middle layer 204.

In accordance with some embodiments of the present invention, the at least one bottom layer 102/middle layer 204, e.g., the at least one anti-Stokes layer may be situated underneath the at least one top layer 104, 206, i.e., underneath the at least one amplification layer (with/without filtration capabilities).

The at least one bottom layer 102/middle layer 204 absorbs selected part of the spectrum, e.g., the bands transmitted via the at least one top layer 104, 206, and loses thermal energy via photon up-conversion, i.e., shifting the wavelengths of the absorbed bands to a shorter wavelength range using anti-Stokes effect active cooling.

It should be noted that the cooling effect is intensified and improved by amplifying the spectral window by the embedment of Stokes shifting materials via the at least one top layer (amplification layer) 104, 206. In accordance with some embodiments, cooling effect by anti-Stokes fluorescence of the at least one bottom layer 102/middle layer 204 may exceed heating effect by Stokes shift of the at least one top layer (amplification layer) 104, 206.

It should be noted that the use of anti-Stokes effect with a range of frequencies (inside the spectral band) rather than a single one does not alter the possibility of performing cooling due to the existence of the anti-Stokes reaction across the entire spectral band.

In accordance with some embodiments of the present invention, the active cooling does not depend on the coherent nature of the radiation, which enables the usage of incoherent solar radiation as the active cooling input power source. The spectral bandwidth may be between ˜10 nm and ˜200 nm.

As described above, the second apparatus for amplifying electromagnetic radiation and cooling of objects and/or object surfaces via anti-Stokes fluorescence 200 may comprise at least one bottom layer 202 which is a reflective layer with IR emission.

In accordance with some embodiments of the present invention, the at least one bottom layer 202 receives the bands transmitted via the middle layer 204 and reflects back the majority of the bands with additional IR emission. Such IR emission passing through the multiple layers and exiting to the atmosphere without absorption, and thus, intensifies the cooling. That is, the IR emission may dissipate heats to the surrounding without the heats being absorbed in the apparatus. In some embodiments, the IR emission may help the apparatus to dissipate heats that cannot be dissipated only by the active cooling layer.

The at least one bottom layer 202, the reflection layer, may be situated underneath all layers since it reflects the light particles that have not been used and/or light particles that “leaked” through the at least one top layer 104, 206. In some embodiments, the reflection layer may also intensify the cooling effect, since the light particles that have not been used and/or light particles that “leaked” through the at least one top layer 104, 206 are reflected back to the at least one top layer 104, 206 and may have another chance to be used for anti-Stokes fluorescence

It should be noted that in cases of electronic equipment the at least one bottom layer 202 may not be used since it comprises metal(s) such as aluminum which may block communication frequencies.

In accordance with some embodiments of the present invention, the at least one bottom layer 202 may be made of porous PDMS or other porous substance with strong optical activity in the LW-FIR region (LW-FIR emission) to increase the degree of cooling.

FIG. 5C illustrates a third apparatus for amplifying electromagnetic radiation and cooling of objects and/or object surfaces via anti-Stokes fluorescence 300 in accordance with some embodiments of the present invention.

The third apparatus may contain: at least one bottom layer 302 which is a reflective layer, at least one first middle layer 304 with IR cooling, at least one second middle layer 306 which is an active cooling layer comprised of a single or multi layered material configured to respond in anti-Stokes fluorescence upon absorption of electromagnetic radiation, and at least one top layer 308 which is an amplifying filter layer. The at least one top layer 308 is comprised of a single or multi-layered material configured to amplify the radiation in the desired spectral band in order to enhance the cooling via the electromagnetic radiation transmitted to the at least one middle layers 304, 306.

In accordance with some embodiments of the present invention, the apparatus for amplifying electromagnetic radiation and cooling of objects and/or object surfaces via anti-Stokes fluorescence 100, 200, 300 may comprise additional layers such as insulation layers as seen in FIGS. 5D and 5E.

FIG. 5D is a schematic illustrating the various layers and possible locations of each layer in an apparatus for amplifying electromagnetic radiation and cooling of objects and/or object surfaces via anti-Stokes fluorescence in accordance with some embodiments of the present invention.

As seen in the figure, at least one IR radiative cooling layer 502 may be situated in one/multiple positions and may be made of various materials.

As seen in the figure, the at least one IR radiative cooling layer 502 may be situated at various locations, i.e., on top/underneath the at least one top layer 104, 206, 308 on top/underneath the at least one bottom layer 102, at least one middle layer 204, at least one first middle layer 304, and at least one second middle layer 306 and/or on top/underneath the bottom layer 202, 302.

The at least one RC (Radiative Cooling) layer 502 may function with or without the at least one top layer 104, 206, 308. For instance, when an interior coating is attached to the windshield of vehicle, the windshield (glass) may be the at least one IR radiative cooling layer 502. The materials for IR radiative cooling layer 502, for example, may be PDMS. The IR radiative cooling layer 502 operates In the Infra red spectrum 8 micron-12 micron. Thus, the IR radiative cooling layer 502 may intensify the cooling effect.

As seen in the figure, the at least one or more insulation layer 504 may be situated underneath the at least one top layer 104, 206, 308 to prevent heat from penetrating into the at least one bottom layer 102, middle layer 204, first middle layer 304, second middle layer 306.

The at least one insulation layer 504 may be situated in between the at least one bottom layer 102, 202, 302 and the surface of the object to be cooled. The at least one insulation layer 504 may be made of HDPE, Nylon 6, and Nylon 6,6, iodide and bromide salts, and materials that are ITVOF. The at least one insulation layer 504 may be transparent so that photons for anti-Stokes shift may pass through the at least one insulation layer 504 and arrive at the active cooling layer to be used for anti-Stokes fluorescence.

The cooling effect by the active cooling layer may be properly achieved since the cooling effect is obtained not by heat emission, but by photon emission

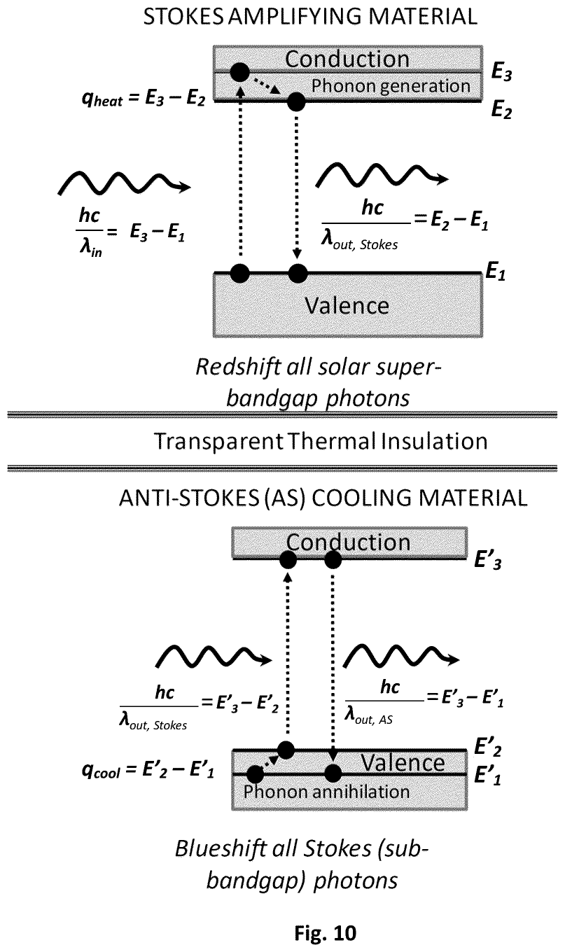

FIG. 10 schematically models a multi-layer apparatus of the present invention for cooling with anti-Stokes fluorescence of amplified incoming electromagnetic radiation. For convenience of modeling, a semiconductor electric configuration is used with a band gap between the valence and conduction bands, which is suitable for absorbing a selected bandwidth of electromagnetic radiation from a wide bandwidth source, e.g., the sun. The selected wavelength, λᵢₙ, corresponds to, E₃−E₁, which is the energy difference between the valence band, E₁, and an excited energy level, E₃, in the conduction bands, which is higher than the base energy level, E₂, of the conduction band. Excess of the incoming electromagnetic energy is converted to phonons, qₕₑₐₜ=E₃−E₂, and the outgoing radiation, λₒᵤₜ, Stokes fluorescence, corresponds to the bandgap, E₂−E₁. This results in heat released to the top layer and a redshift of the incoming radiation. The incoming radiation is, thus, amplified by providing photons with wavelengths suitable for generating a cooling effect at the bottom layer. Electrons of the cooling layer absorb the outgoing electromagnetic radiation, λₒᵤₜ, and additional thermal energy, phonons, at the valence band. The annihilated phonons generate a cooling effect, q_{cool}=E′₂−E′₁, (E′₂—highest ground level of the valence band; E′₁—energy level lower than E′₂) and provide the additional energy for exciting the electrons to the conduction band, λ_{out,Stokes}˜1/(E′₃−E′₂), where E′₃ is the lowest energy level of the conduction band. The excited electrons at the conduction band fall back to below ground state, thereby causing a blueshift of the incoming radiation, λ_{out,Anti-Stokes}˜1/(E′₃−E′₂), in the cooling layer in anti-Stokes fluorescence. In some embodiments of the present invention, the thermal energy, which is produced in the amplifying top layer, dissipates to the surrounding or cancels out with the absorption of phonons in the cooling layer. Alternatively, in some embodiments of the present invention, a thermal insulation layer is placed between the amplifying and cooling layers as shown in FIG. 10. This insulation layer is transparent to the outgoing electromagnetic radiation from the amplifying layer, which allows the redshifted photon to pass through to the cooling layer.

In accordance with some embodiments of the present invention, the apparatus for amplifying electromagnetic radiation and cooling of objects and/or object surfaces via anti-Stokes fluorescence 100, 200, 300 may comprise an additional layer such as an adhesive layer/magnetic layer underneath the bottom layer for attaching the apparatus for amplifying electromagnetic radiation and cooling of objects and/or object surfaces via anti-Stokes fluorescence 100, 200, 300 to the object to be cooled.

In addition, the apparatus for amplifying electromagnetic radiation and cooling of objects and/or object surfaces via anti-Stokes fluorescence 100, 200, 300 may comprise an additional layer, at least one upper mechanical layer to prevent damages such as physical, chemical or electrical damages, to minimize the degradation of apparatus 100, 200, 300 over time, and to isolate thermally and electrically the at least one bottom layer 102, middle layer 204, first middle layer 304, second middle layer 306 from environmental impacts.

In accordance with some embodiments of the present invention, the at least one upper mechanical layer may prevent scratches and bruises, at least one upper mechanical layer to prevent static electricity and dust accumulation and to facilitate easy cleaning and the like. The at least one upper mechanical layer may be made of Polyurethane The at least one upper mechanical layer may be transparent so that photons for anti-Stokes shift may pass through the at least one upper mechanical layer and arrive at the active cooling layer. FIG. 5E is a schematic illustrating an apparatus for amplifying electromagnetic radiation and cooling of objects and/or object surfaces via anti-Stokes fluorescence 400 comprised of multiple layers in accordance with some embodiments of the present invention.

As seen in the figure, in addition to the two layers necessary for cooling, as described in FIG. 5A, i.e., (a) at least one active cooling layer comprised of a single or multi layered material configured to respond in anti-Stokes fluorescence upon absorption of electromagnetic radiation, and (b) at least one top layer configured to amplify the electromagnetic radiation transmitted to active cooling layer.

The apparatus for amplifying electromagnetic radiation and cooling of objects and/or object surfaces via anti-Stokes fluorescence 400 may comprise multiple additional layers such as back reflector layer/s 402, radiative cooling layer/s 404, anti-Stokes layer/s 406, transparent thermal barrier/s 408, Stokes filter/s 410, and UV filter/s 412 for intensifying and maximizing the cooling.

In accordance with some embodiments of the present invention, the materials for UV filter/s 412, for example, may be 9Be+. The UV filter/s 412 operates 300 nm. Thus, the UV filter/s 412 may intensify the cooling effect.

It should be noted that the apparatus for amplifying electromagnetic radiation and cooling of objects and/or object surfaces via anti-Stokes fluorescence 100, 200, 300, 400 may comprise multiple layers where each layer may have either one or more activities. For instance, the apparatus may comprise a first layer having filtering means and a second layer having amplification means. Alternatively, the apparatus may comprise a single layer having both filtering and amplification means. In accordance with some embodiments of the present invention, the multiple layers may be linked to each other through an adhesion matrix domain. Thus, the role of an adhesion matrix is two-fold: (a) attaching the layers to one another, and (b) protecting the layers from environmental damage (moisture and the like).

In accordance with some embodiments of the present invention, the matrix may be used to attach the layers via heat or any other means to the surface of the object to be cooled.

In accordance with some embodiments of the present invention, the apparatus for amplifying electromagnetic radiation and cooling of objects and/or object surfaces via anti-Stokes fluorescence 100, 200, 300, 400 may comprise semiconductor materials for wide band-gap anti-Stokes cooling under wide spectrum solar radiation, and/or RE-doped synthetic materials for obtaining anti-Stokes fluorescence using wide range solar radiation, and/or organic dyes and quantum dots are used for obtaining anti-Stokes fluorescence using wide range solar radiation.

In accordance with some embodiments of the present invention, the multiple layers of the apparatus for amplifying electromagnetic radiation and cooling of objects and/or object surfaces via anti-Stokes fluorescence 100, 200, 300, 400 are provided in film(s).

In accordance with some embodiments of the present invention, various materials have been investigated. Some of the materials which were found to be good candidates to be used as active anti-Stokes cooling layers and to operate by either lasers or solar radiation at certain wavelength ranges are described as follows:

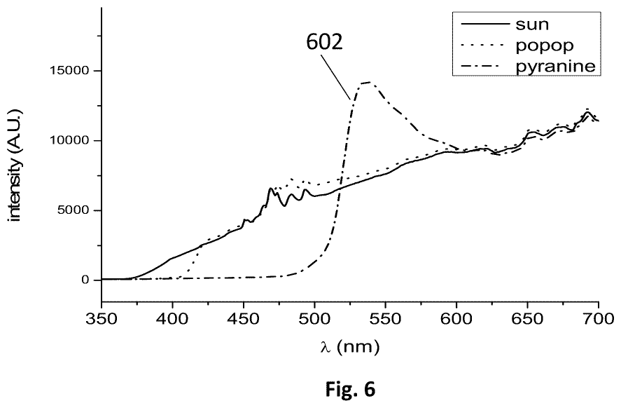

FIG. 6 is intensity as a function of time plot showing a Stokes shift of Pyranine dye 602 amplifying the solar spectrum. Seen in the figure is an amplification of the spectral window between 525 nm and 600 nm.

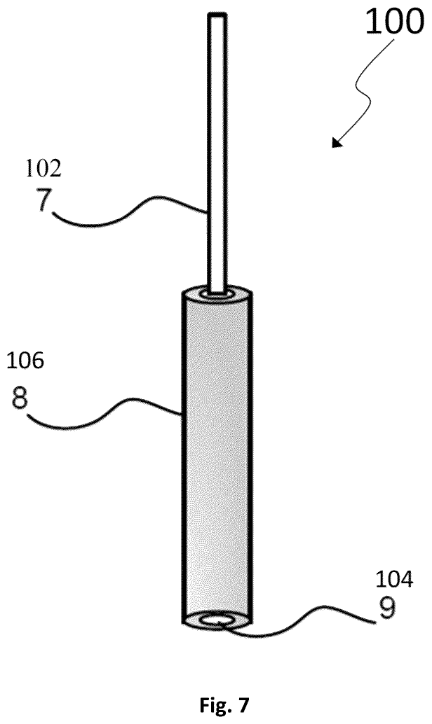

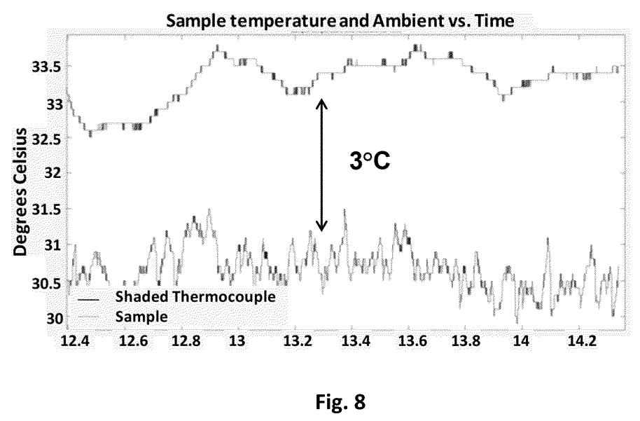

FIG. 7 schematically illustrates one particular implementation of the apparatus for amplifying electromagnetic radiation and cooling of objects and/or object surfaces via anti-Stokes fluorescence 100, 200, 300, 400 of the present invention. As seen in the figure, the shell is the top layer 104, 206, 308, 412 that filters and amplifies the incoming radiation to the desired wavelength range as depicted in FIG. 8.

The core of the apparatus for amplifying electromagnetic radiation and cooling of objects and/or object surfaces via anti-Stokes fluorescence 100, 200, 300, 400 is the bottom layer 202, 302, 402 that reflects with IR emission, and between them is the active material fluorescing layer 102, 204, 304, 306, 406 that receives and absorbs the radiation in the filtered wavelength range and responds by emitting radiation in anti-Stokes fluorescence. In one particular example, the structure of the apparatus for amplifying electromagnetic radiation and cooling of objects and/or object surfaces via anti-Stokes fluorescence 100, 200, 300, 400 may be used in textiles for any use for cooling objects, bodies and spaces by covering them with the protective cooling textile or shielding them from a heat source. Particular applications of such covers and shields are selected from clothing, drapes, shades, curtains, bags, camping gear, food cooler covers and the like.

FIG. 8 shows the results of a cooling experiment carried out outdoors with the apparatus for amplifying electromagnetic radiation and cooling of objects and/or object surfaces via an apparatus for amplifying electromagnetic radiation and cooling of objects and/or object surfaces via anti-Stokes fluorescence 100, 200, 300, 400. The cooling film, composed of a reflective layer, a radiation amplifying layer and an active cooling layer, is measured on a summer day where the air temperature was 33° C. with a relative humidity of 50 percent.

As seen in the figure, the apparatus for amplifying electromagnetic radiation and cooling of objects and/or object surfaces via anti-Stokes fluorescence 100, 200, 300, 400 lowered the temperature by 3° C.

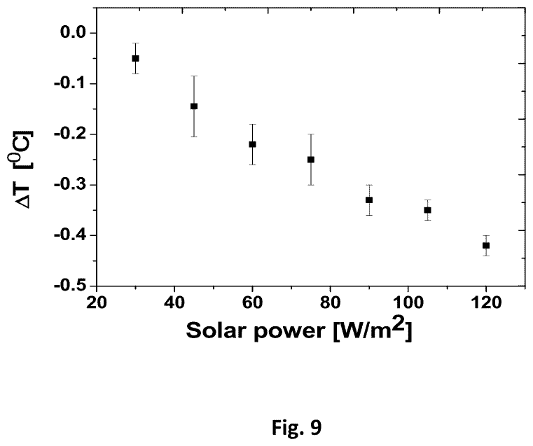

FIG. 9 shows the results of a cooling experiment carried out with the apparatus for amplifying electromagnetic radiation and cooling of objects and/or object surfaces via anti-Stokes fluorescence indoors where the air temperature was 22° C.

In the experiment, 100 mW light was projected on a sample in liquid form. The light was filtered and amplified by the apparatus for amplifying electromagnetic radiation and cooling of objects and/or object surfaces via anti-Stokes fluorescence.

It should be noted that anti-Stokes fluorescence cooling experiments described in the present invention may be carried out without electricity input, moving parts, gases, liquids and any additional components other than the apparatus for amplifying electromagnetic radiation and cooling of objects and/or object surfaces via anti-Stokes fluorescence 100, 200, 300, 400 defined above.

Perovskites—Perovskites are optoelectronic materials that have the common formula:

A′ₐB²_{b}X_{c}

Loredana Prodesescu et al. (Nano Lett., 2015, 15, 3692-3696) developed inorganic perovskites using cheap and effective materials to get stable and luminescent QDs (Quantum Dots). These unique materials can be modulated with different quantum size effects and band gap. They operate in the entire visible spectral region between 400-700 nm. These quantum dots are characterized by narrow emission line widths between 12-42 nm and have magnificent quantum yields near unity.

8-hydroxy-1,3,6-pyrenetrisulfonic acid trisodium salt fluorescent molecule—refers to Pyranine along with all its substitutes and derivatives. This molecule is well known and used as a tracer and as a fluorescent pH indicator. Its fluorescent emission is strongly dependent on its pH. Pyranine's excitation range is between 400 and 460 nm.

9,10-Bis(phenylethynyl)anthracene—refers to BPEA along with all its substitutes and derivatives. BPEA is a well known fluorescent aromatic hydrocarbon fluorophore and has a highly efficient quantum yield. In addition, it has unique optical and electronic characteristics making it a promising material for solar cells, light emitting diodes, etc.

The optical properties in the visible range appear from 335 to 500 nm. 9H-xanthene, 10H-9-oxaanthracene—refers to the family of Xanthines and all its substitutes and derivatives. Xanthine dyes represent a wide class of compounds. Some may exhibit fluorescent properties which are studied here. These well known types of compounds are ubiquitous in the human body and closely related to the DNA bases: guanine and adenine. These types of dyes are capable to form supramolecular structures that exhibit unique chemical and physical properties. It has a huge UV-vis absorption that can range from 300 to 700 nm.

Diketocyclobutenediol refers to Squaraine dyes and all its derivatives and substitutions. Squaraine dyes are a class of organic compounds that exhibit narrow absorption bands in the near infrared that range between 700-1500 nm. Including to their unique and intense absorption band they also exhibit high molar absorption coefficient and good photoconductivity and photostability.

bis(3-methylindolyl)-2-pyridylmethane—Refers to Dipyrromethane and all its substitutes and derivatives. They are used as intermediates when synthesizing fluorescent compounds. Usually, the synthesis is acid-catalyzed condensation. BODIPY are fluorescent compounds synthesized from the Dipyrromethane family. BODIPY has the same core as Dipyrromethane but has the addition of two fluorenes and the subtraction of two hydrogens. These BODIPY dyes are used to label amino acids and nucleotides. They have a UV-vis absorption range from 500 to 750 nm.

Tetramethylindo(di)-carbocyanines—Refers to Cyanine fluorophores along with all of its substitutes and derivatives. These dyes are quaternary ammonium salts and are used in solar energy conversion and pH sensing. They are also used with labeling proteins, antibodies, and peptides. They have a UV-Vis absorption spectrum ranging from 400 to 900 nm.

The results of an experiment in which the solar spectrum passes through a Pyranine layer and measured with a spectrometer are illustrated in FIG. 6.

In accordance with some embodiments of the present invention, particular non-limiting examples of compounds that can be part of the apparatus for amplifying electromagnetic radiation and cooling of objects and/or object surfaces via anti-Stokes fluorescence 100, 200, 300, 400 are listed below:

Table I illustrates examples of compounds that can be used for forming the bottom layer 102/middle layer 204, 306, 406 of the apparatus for cooling of objects and/or object surfaces via anti-Stokes fluorescence 100, 200, 300, 400.

TABLE I

| Material | Wavelength | | Efficiency or QY |
|---|---|---|---|
| Cadmium Sulfide | 505 nm-560 nm | | 4.8% efficiency from |
| | | | power on to cooling |
| Gallium Arsenide (GaAs) | ~600 nm-~660 nm | | 94% efficiency. Not tested |
| quantum wells | (1.94 eV average) | | yet |
| Ytterbium-doped yttrium | 1023 | nm | 9 W laser, cooling power of |
| lithium fluoride (Yb:YLF) | | | 140 mW up to 165° K. 2% |
| crystal | | | efficiency |
| Ytterbium-doped tungstate | 1010 nm-1050 nm | | Positive efficiency of 2% |
| crystal (Yb:KGW) | | | |
| Fluorozirconate glass | 1015 | nm | 2% |
| (ZBLANP) doped with 1 | | | |
| wt % Yb3+ | | | |
| 9Be+ | 300 | nm | unknown |
| Cesium | 894 nm + 795 nm + 761 nm | | 3% |
| CdS/ZnS | 610 nm-660 nm | | ~2.5% |
| Perovskites | 400-700 | nm | 90-unity |
| Pyranine | 400 and 460 | nm | 90-unity |
| BPEA | 335 to 500 | nm | 80-unity |
| Rhodamine 101 (Xanathine | 500-630 | nm | 90-unity |
| family) | | | |
| Pyrromethene 567 (Bodipy | 522 to 590 | nm | 90-unity |
| family) | | | |

Table I details the spectral band required for each of the materials presented therein to obtain anti-Stokes fluorescence and the efficiency of conversion of absorbed to emitted radiation.

It should be noted that any fluorescent material with QY (Quantum Yield) of 90% or higher may be used for forming anti Stokes cooling of objects and/or object surfaces via anti-stokes fluorescence 100, 200, 300, 400.

In some embodiments, the at least one active cooling layer may include more than two layers, each of which may be made of different active cooling material in Table I. Since the spectral bands of active cooling materials are different from material to material, the materials for the respective layers may be selected so that the spectral bands may be for example Perovskites, CdS or ZnS with fluorescence in the range of 610-660 nm, and GaAs quantum wells with fluorescence range of ˜600-˜660 nm.

Table II illustrates examples of compounds that can be used for forming the top layer 104, 206, 308, 412 of the apparatus for amplifying electromagnetic radiation so that the layer underneath, the bottom layer 102/middle layer 204, 306, 406 (see table 1), will be cooling of objects and/or object surfaces via anti-Stokes fluorescence 100, 200, 300, 400. In accordance with some embodiments of the present invention, the filter layer may comprise compounds detailed in table II to obtain amplification of the band entering the active layer.

TABLE II

| Material | Emittance Wavelength |
|---|---|
| Pyranine | 480-600 nm |
| Perovskites | 400-700 nm |
| 1,3-Bis[4-(dimethylamino)phenyl]-2,4- | 600-700 nm |
| dihydroxycyclobutenediylium dihydroxide, | |
| bis(inner salt) [Squarylium dye III] | |
| Cyanine-3b (Cyanine family) | 500-650 nm |
| Pyrromethene 567 (Bodipy Family) | 522 to 590 nm |
| Perylene | 400-700 nm |
| Coumarin 6 (Coumarin Family) | 450-700 nm |
| 9,10-Bis(phenylethynyl)anthracene | 435-600 nm |
| 1,4-bis(5-phenyloxazol-2-yl) benzene | 360-500 nm |
| (POPOP) | |
| Perylene, PMI | 500-800 nm |
| Perylene, PMI(OR) | 500-800 nm |
| Perylene, PMI(OR)3 | 500-800 nm |
| Perylene, PDI | 500-700 nm |
| Fluorescein | 500-680 nm |
| Rhodamine 123 | 490-700 nm |
| Rhodamine 6G | 500-750 nm |
| Rhodamine 101 inner salt | 535-750 nm |
| Sulforhodamine 101 | 550-780 nm |
| Rhodamine family and derivatives | 480-750 nm |

It should be noted that any fluorescent material with QY of 80% or higher may be used for forming the top layer 104, 206, 308, 412 of the apparatus for amplifying electromagnetic radiation and cooling of objects and/or object surfaces via anti-Stokes fluorescence 100, 200, 300, 400.

A material of the active cooling layer and that of the amplifying filter layer may compatibly be selected. The spectral band of the amplifying filter layer may absorb radiation within the range of 400-460 nm and fluoresce at the range of 525-600 nm (see FIG. 6) compared to that of the active cooling layer that fluoresce at 300 nm. Each of the absorption and fluorescence wavelength ranges of pyranine may be broad or narrow and overlap each other, depending on different parameters of the layer that contains pyranine, e.g., pyranine concentration.

Table III illustrates examples of compounds that can be used for forming the bottom layer 202, 302, 402 of the apparatus for amplifying electromagnetic radiation and cooling of objects and/or object surfaces via anti-Stokes fluorescence 200, 300, 400.

TABLE III

Material
Continuous or Porous PTFE or PTFE nano or micro particles
Continuous or Porous PDMS or PDMS nano or micro particles
Continuous or Porous SiO₂ or SiO₂ nano or micro particles
Continuous or Porous etched ceramics such as Alumina
TiO₂
BaSO₄
Metal
SiO₂
Si-Polymers
PTFE
PVDF

Table III details some of the materials possible for the bottom layer reflecting above 90% with high emissivity in the IR.

It should be noted that all layers may be continuous/non-continuous, for instance, may contain openings to allow communication frequencies to pass therethrough.

In accordance with some embodiments, the apparatus for amplifying electromagnetic radiation and cooling of objects and/or object surfaces via anti-Stokes fluorescence 100, 200, 300, 400 may be used to cool various objects provided that:
The coating, e.g., the apparatus for amplifying electromagnetic radiation and cooling of objects and/or object surfaces via anti-Stokes fluorescence 100, 200, 300, 400 may be exposed to the sun.
The apparatus 100, 200, 300 400 is positioned under a transparent object such as glass or water or a transparent coating that is exposed to the sun.

The apparatus 100, 200, 300 400 is positioned underneath a perforated object such as a mesh exposed to the sun. In accordance with some embodiments of the present invention, the apparatus for amplifying electromagnetic radiation and cooling of objects and/or object surfaces via anti-Stokes fluorescence 100, 200, 300, 400 of the present invention may be suitable for small and large scales and practically for any object with surface on which the layer substance can be applied or overlaid, e.g., roof, wall, car, ship, tent, clothing, etc.

In accordance with some embodiments of the present invention, the apparatus for amplifying electromagnetic radiation and cooling of objects and/or object surfaces via anti-Stokes fluorescence 100, 200, 300, 400 may be implemented in paint, fabric, and the like.

Paint comprised of the apparatus for amplifying electromagnetic radiation and cooling of objects and/or object surfaces via anti-Stokes fluorescence 100, 200, 300, 400 may be applicable to different materials and surfaces, for instance, concrete, fabrics, glass windows and so on.

Namely, a technology for fabricating such multi-layer paint, i.e., paint comprised of the apparatus for amplifying electromagnetic radiation and cooling of objects and/or object surfaces via anti-Stokes fluorescence 100, 200 having physical and chemical compatibilities with surfaces of different materials, proves to be substantially efficient for multiple applications that would otherwise not be able to enjoy any anti-Stokes fluorescence-based cooling.

In accordance with some embodiments of the present invention, the materials selected for making such multi-layer paint are not only efficient for cooling but also provide long term compatibility with the surfaces with which they come in contact. Such multi-layer paint proves long term activity when overlaid on surfaces or imbedded in objects made of different materials.

In accordance with some embodiments of the present invention, the at least one top, middle and bottom layers may be incorporated into textile, wherein the at least top layer is incorporated into outer surface of fibers of the textile, the bottom layer is incorporated into core of the fibers, and the middle layer is in between.

In accordance with some embodiments of the present invention, the apparatus for amplifying electromagnetic radiation and cooling of objects and/or object surfaces via anti-Stokes fluorescence 100, 200, 300, 400 may cool solids such as metals (for instance, vehicles), ceramics, glasses (for instance, glasses of buildings), films and fabrics (tents/textiles/insulation for shipments and the like).

In accordance with some embodiments of the present invention, the apparatus for amplifying electromagnetic radiation and cooling of objects and/or object surfaces via anti-Stokes fluorescence 100, 200, 300, 400 may cool liquids such as water/chemicals/or waxes (which solidify at night and re-liquefy during the day—when used as a “cold capacitor” as well as gases such as water vapor (for the purpose of extracting water from air) and air (for more efficient cooling in air conditioning).

In accordance with some embodiments of the present invention, the apparatus for amplifying electromagnetic radiation and cooling of objects and/or object surfaces via anti-Stokes fluorescence 100, 200, 300, 400 may be used in various applications, for instance, in agriculture in which it is essential to keep the temperature low during the growing season, between the harvest and storage, and during storage.

In accordance with some embodiments of the present invention, the apparatus for amplifying electromagnetic radiation and cooling of objects and/or object surfaces via anti-Stokes fluorescence 100, 200, 300, 400 may be used in barns/chicken coops, tents/caravans/small ships/automotive field including cars/buses/trucks/trains and the like/buildings/barracks/buildings/airports/train stations/data centers/industrial trade and the like.

In accordance with some embodiments of the present invention, the apparatus for amplifying electromagnetic radiation and cooling of objects and/or object surfaces via anti-Stokes fluorescence 100, 200, 300, 400 may be used for extracting water from air, for transporting fruits and vegetables, for preservation of fuels and chemicals that will not evaporate, for protective clothing and clothing for athletes/firefighters/rescuers (such as soldiers and police), for protection of electronic equipment that stands outside, including screens/cellphones/radars and the like, for protection for outdoor analytical equipment that requires non-extreme temperatures or too sharp changes, for the military field includes tanks/ammunition/planes and helicopters on the ground/thermal camouflage and the like, and for electronic equipment in space and at high altitude.

1. An apparatus for amplifying a cooling mechanism based on absorption of incoherent non-monochromatic electromagnetic/solar radiation and anti-Stokes fluorescence, said apparatus comprising:
at least one bottom layer, said at least one bottom layer is comprised of a single or multi layered material configured to emit IR radiation;
at least one middle layer, said at least one middle layer is comprised of a single or multi layered material configured to respond in anti-Stokes fluorescence upon absorption of electromagnetic radiation; and
at least one top layer, said at least one top layer is comprised of a single or multi layered material configured to filter said electromagnetic radiation and transmit selected spectral band(s) of said electromagnetic radiation transmittable to said at least middle layer and said at least one bottom layer, wherein said at least one middle layer is configured to respond to one of said selected spectral band(s), wherein said at least one bottom layer is configured to respond to a second of said selected spectral band(s), wherein said one and second spectral bands are the same as or different from each other.

2.-4. (canceled)

4. The apparatus according to claim 1, wherein said at least one bottom layer is configured to reflect at least 50% of the electromagnetic radiation.

5. The apparatus according to claim 1 further comprising at least one layer configured to emit IR radiation.

6. The apparatus according to claim 1 further comprising at least one insulation layer, wherein said insulation layer is selected from an insulation layer that is transparent to electromagnetic radiation, an insulation layer that is made from very low IR absorption polymers and materials, air, an insulation layer that is a film made of materials that are ITVO (Infrared Transparent Visible Opaque), an insulation layer which is a film with thickness that ranges between 1 millimeter and 10 centimeters, wherein transparency to electromagnetic radiation of said film reduces proportionally to its thickness, and an insulation layer which is a film made of electromagnetic radiation selectively transparent material is selected from porous PTFE, PMMA (Polymethylmethacrylate) and PS Polystyrene).

7. (canceled)

8. The apparatus according to claim 6, wherein said insulation layer is a microporous film with pores with diameter smaller than 5 μm.

9.-17. (canceled)

18. The apparatus according to claim 6, wherein said insulation layer is a porous PTFE film.

19. (canceled)

20. The apparatus according to claim 1 further comprising at least one adhesive layer underneath the at least one bottom layer for attaching said apparatus to an object to be cooled.

21. The apparatus according to claim 1 further comprising at least one upper mechanical layer to secure said apparatus against mechanical deterioration.

22. The apparatus according to claim 1, wherein said at least one middle layer and at least one top layer are linked to each other through an adhesion matrix domain.

23. The apparatus according to claim 1, wherein said at least one bottom layer and/or said at least one top layer and/or said at least one middle layer are provided in film(s).

24.-27. (canceled)

28. The apparatus according to claim 1, wherein said at least one bottom layer is comprised of a fluorescent material with QY of at least 90%.

29. The apparatus according to claim 1, wherein said at least one middle layer is comprised of at least one material selected from Cadmium Sulfide, Gallium Arsenide (GaAs) quantum wells, Ytterbium-doped yttrium lithium fluoride (Yb:YLF) crystal, Ytterbium-doped tungstate crystal (Yb:KGW), Fluorozirconate glass (ZBLANP) doped with 1 wt % Yb3+, 9Be+, Cesium, CdS/ZnS, Perovskites, Pyranine, BPEA, Rhodamine 101 (Xanathine family), and Pyrromethene 567 (Bodipy family).

30. The apparatus according to claim 1, wherein said at least one middle layer is comprised of a fluorescent material with QY of at least 90%.

31. (canceled)

32. The apparatus according to claim 1, wherein said at least one bottom layer is comprised of at least one material selected from Continuous or Porous PTFE or PTFE nano or micro particles, Continuous or Porous PDMS or PDMS nano or micro particles, Continuous or Porous SiO₂ or SiO₂ nano or micro particles, Continuous or Porous etched ceramics such as Alumina, TiO2, BaSO₄, Metal, SiO₂, Si-Polymers, HDPE (High Density Polyethylene), PS (Polystyrene), Germania, Alumina, Titania, Barium Sulfate or nano or microparticles thereof, wherein said nano or microparticles are free-standing or embedded in a film, matrix or membrane, wherein said continuous PDMS is provided as a film, wherein thickness of said continuous PDMD film is between 3.5 μm and 5 μm, wherein said porous PDMS is provided as a film, wherein total mass of said porous PDMS film is approximately equal to mass of said continuous PDMS film with a thickness in the range of 3.5 μm to 5 μm, preferably with a thickness of 4 μm.

33.-42. (canceled)

43. The apparatus according to claim 32, wherein said bottom layer is a film with a thickness in the range of 1-1000 μm.

44. The apparatus according to claim 1, wherein said at least one bottom layer is made of porous substance with strong optical activity in a LW-FIR region.

45.-47. (canceled)

48. The apparatus according to claim 1, wherein said apparatus is incorporated in a textile.

49.-50. (canceled)

51. The apparatus according to claim 1, wherein said at least one top layer is further comprised of a single or multi layered material configured to amplify selected spectral band(s) of said electromagnetic radiation transmittable to said at least one middle layer.

52. The apparatus according to claim 1, wherein a spectral band for the anti-Stokes fluorescence in the at least one middle layer is included within from 300 nm to 1500 nm.

53. The apparatus according to claim 1, wherein the at least one bottom layer emits IR radiation within an infrared spectrum from 8 μm to 14 μm.
